(19) United States
(12) Patent Application Publication
(10) Pub. No.: US 2024/0427236 A1
(43) Pub. Date: Dec. 26, 2024

(54) PROCESS CONTROL PATTERN TO IMPROVE NANOIMPRINT DETACHING PROCESS

(71) Applicant: GOOGLE LLC, Mountain View, CA (US)

(72) Inventors: Lu Tian, Palo Alto, CA (US); Wei Jin, Saratoga, CA (US); Kang Luo, San Jose, CA (US); Thomas Mercier, Weston, FL (US)

(21) Appl. No.: 18/755,207

(22) Filed: Jun. 26, 2024

Related U.S. Application Data
(60) Provisional application No. 63/523,169, filed on Jun. 26, 2023.

(51) Int. Cl. G03F 7/00; B29C 59/00; B29C 59/02; G02B 6/13

(52) U.S. Cl. CPC G03F 7/0002; B29C 59/002; B29C 59/022; G02B 6/13; G03F 7/0007; B29K 2995/0026; B29K 2995/0027

(57) ABSTRACT

A method of nanoimprinting a waveguide includes forming a working stamp having at least one waveguide feature pattern and at least one process control feature pattern. The working stamp is pressed into a waveguide workpiece thereby forming waveguide features in one or more functional waveguide zones of the waveguide workpiece and one or more sets of process control features in one or more regions outside of the one or more functional waveguide zones. The working stamp is detached from the waveguide workpiece.

### BACKGROUND

Head-mounted devices (HMDs), heads-up displays (HUDs) and other near-eye display systems often employ waveguides that utilize surface gratings or holographic gratings for various light manipulation purposes, such as the incoupling of display light into the waveguide or the outcoupling of display light from the waveguide toward the direction of a user's eye. A common approach to fabrication of a waveguide with surface gratings relies on the use of a working stamp that has the negative, or inverse, pattern of the intended pattern of the surface gratings. The working stamp is pressed into the appropriate location on the surface of a waveguide workpiece to form the corresponding surface grating pattern at that surface of the waveguide workpiece. After withdrawing the working stamp from the waveguide workpiece, a curing process then may be applied to the area in which the slanted gratings were formed so as to cure and harden the slanted gratings. To form the working stamp itself, an imprint replication master is fabricated, with the imprint replication master itself having the same pattern as the gratings to be formed in the waveguide workpiece, which is the negative, or inverse, pattern of the working stamp. The imprint replication master is pressed into a workpiece composed of suitable working stamp material so as to form the negative/inverse grating pattern in the workpiece, and then the workpiece is cured, resulting in the working stamp.

### SUMMARY OF EMBODIMENTS

In accordance with one aspect, a method includes forming a working stamp having at least one waveguide feature pattern and at least one process control feature pattern. The working stamp is pressed into a waveguide workpiece thereby forming waveguide features in one or more functional waveguide zones of the waveguide workpiece and one or more sets of process control features in one or more regions outside of the one or more functional waveguide zones. The working stamp is detached from the waveguide workpiece.

In accordance with another aspect, a stamp for waveguide nano-imprint lithography includes one or more functional waveguide zones, at least one waveguide feature pattern formed within the one or more functional waveguide zones for forming waveguide features in at least one waveguide, and at least one process control feature pattern formed in one or more regions outside of the one or more functional waveguide zones.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a diagram illustrating a master stamp aligned with a stamp workpiece in accordance with some embodiments.

FIG. 2 is a diagram illustrating the master stamp of FIG. 1 partitioned into multiple master stamps in accordance with some embodiments.

FIG. 3 is a diagram illustrating the master stamp of FIG. 1 being pressed into the stamp workpiece in accordance with some embodiments.

FIG. 4 is a diagram illustrating a working stamp after the master stamp has been detached from the stamp workpiece of FIG. 4 in accordance with some embodiments.

FIG. 5 is a diagram illustrating the stamp workpiece of FIG. 5 aligned with a waveguide workpiece in accordance with some embodiments.

FIG. 6 is a diagram illustrating the stamp workpiece of FIG. 5 being pressed into the waveguide workpiece in accordance with some embodiments.

FIG. 7 is a diagram illustrating the waveguide workpiece after the working stamp of FIG. 6 has been detached and having waveguide feature patterns and process control feature patterns formed therein in accordance with some embodiments.

FIG. 8 is a diagram illustrating various configurations of process control feature patterns in accordance with some embodiments.

FIG. 9 is a diagram illustrating various distributions and configurations of process control feature patterns formed on a waveguide workpiece in accordance with some embodiments.

FIG. 10 is a diagram illustrating various distributions and layout configurations for process control feature patterns formed on a waveguide workpiece in accordance with some embodiments.

FIG. 11 is a flow diagram illustrating an example method of fabricating waveguide features in a waveguide workpiece and fabricating process control features in non-functional zones of the waveguide workpiece using nanoimprint lithography processes in accordance with at least some embodiments.

FIG. 12 is a block diagram of a near-eye display (NED) system in accordance with some embodiments.

### DETAILED DESCRIPTION

Typically, a working stamp is implemented in the form of a stamp film that is composed of a flexible plastic material and which is attached to a stamp tape held by a stamp frame. The stamp frame typically has a circular, elliptical, or rectangular shape, and is manipulated by a replication tool to press the stamp film into the waveguide material of the waveguide workpiece and then to detach the stamp film from the waveguide material. For example, during the detaching process, the stamp frame is lifted with controlled speed from one edge to an opposing edge. The local speed of detachment often depends on the local pattern format and pattern density. For example, the presence of slanted gratings or a high density of gratings in one region may necessitate a slower detachment speed for that region compared to another region with only vertical gratings or with a lower density of gratings. This is in part because the surface in contact with the working stamp in a given region is proportional to the number of surface grating features in that area, as well as the pattern aspect ratios and pattern density of such surface grating features, all of which contribute to the amount of friction experienced between the working stamp and the waveguide workpiece during the detachment process.

However, even with due care and a suitable speed of detachment, the detachment process of the working stamp can cause pattern damage and/or partial pattern replication due to stamp tape deformation resulting from factors such as uneven detaching speed or uneven application of force. For example, an uneven local detachment in a region with non-uniform pattern distribution can cause local stamp tape deformation, such as a bend in the stamp tape. This bend emphasizes local strain, and when combined with a high-speed detaching process, can cause the stamp tape to exceed its elastic tolerance in the bend region, potentially leading to breakage and partial peeling. Additionally, different directions of slant grating features in adjacent regions can exacerbate the partial peeling issue during working stamp detachment.

As such, the following describes embodiments of systems and methods for addressing the challenges of detaching a working stamp from a waveguide workpiece during the nanoimprint process. As described in greater detail below, a working stamp is configured to employ process control patterns distributed across its interfacing surface to improve detachment initiation and continuity and to reduce “popping” during final detachment. The process control patterns are sets of features formed into the working stamp in areas outside the functional pattern zones of the waveguide workpiece. These features, which can be bar-shaped, V-shaped, W-shaped, or the like, improve the local pattern distribution and local pattern density where they are implemented. The sequence of these pattern features maintains consistent contact between the working stamp and the waveguide workpiece during detachment, similar to a zipline, thereby enhancing surface pattern distribution, density uniformity, and uniformity of local contact between the working stamp and the waveguide workpiece. These features, in at least some embodiments, are located in areas of the working stamp corresponding to non-functional zones of the workpiece to avoid impacting barcoding, singulation, or inline metrology processes. Each pattern element, in at least some embodiments, has length dimensions in the tens or hundreds of microns, width dimensions from 1 to 10 microns, and depths equivalent to the functional grating feature depths, although other dimensions are also applicable. The length and arrangement of these “ziplines”, in at least some embodiments, are varied based on the desired detachment control for specific regions. For example, bar-shaped patterns provide more surface contact along a parallel detach line, double-V patterns provide moderate contact orthogonal to the zipline, and V-shaped patterns provide less contact along the detach line. The techniques described herein are also applicable to the imprint master (e.g., master stamp) when forming the working stamp.

Note that in the following, certain orientational terms, such as top, bottom, front, back, and the like, are used in a relative sense to describe the positional relationship of various components. These terms are used with reference to the relative position of components either as shown in the corresponding figure or as used by convention in the art and are not intended to be interpreted in an absolute sense with reference to a field of gravity. Thus, for example, a surface shown in the drawing and referred to as a top surface of a component would still be properly understood as being the top surface of the component, even if, in implementation, the component was placed in an inverted position with respect to the position shown in the corresponding figure and described in this disclosure. Further, note that certain positional terms, such as co-planar or parallel, will be understood to be interpreted in the context of fabrication tolerances or industry standards. For example, co-planar shall be understood to mean co-planar within applicable tolerances as a result of one or more fabrication processes affecting the components indicated to be co-planar, or co-planar within a tolerance utilized in the appropriate industry or fabrication technology. Moreover, it will be appreciated that for simplicity and clarity of illustration, components shown in the figures have not necessarily been drawn to scale. For example, the dimensions of some of the components may be exaggerated relative to other components. It also should be noted that the terms “contact”, “contacts”, “contacting”, or their equivalents refer to, for example, components, such as layers, features, or surfaces being in physical (direct) contact or indirect contact through one or more intermediate layers, features, or surfaces, or the like.

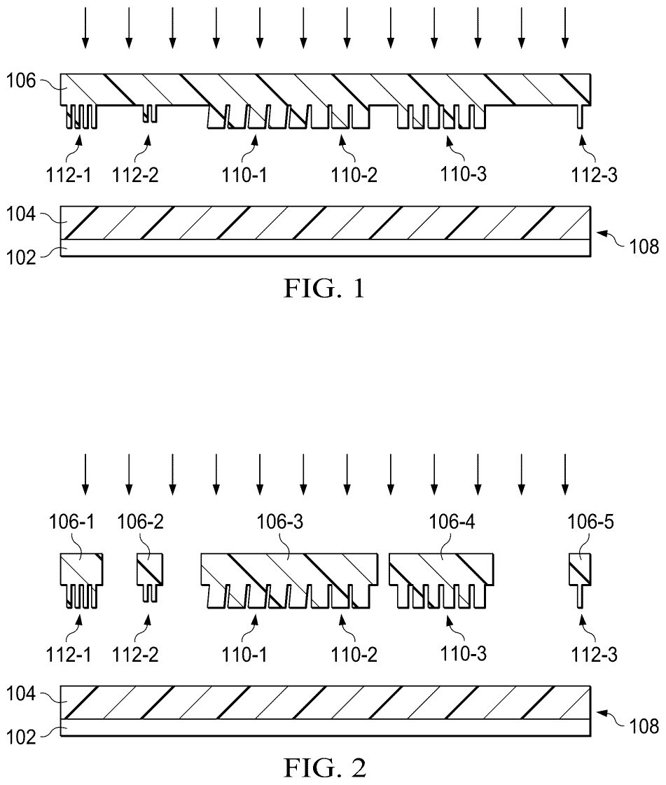

FIG. 1 to FIG. 7 illustrate various processes for fabricating waveguide features in a waveguide workpiece and also for fabricating process control features in non-functional zones of the waveguide workpiece using nano-imprint lithography processes in accordance in accordance with at least some embodiments. FIG. 1 illustrates an initial arrangement of a substrate 102, a working stamp layer or film 104 (also referred to herein as “stamp layer 104”), and a master stamp 106. The stamp layer 104 is composed of any of a variety of suitable soft materials that subsequently can be cured or otherwise transformed into a harder state, such as an uncured polymer or resin. The stamp layer 104 is formed on the substrate 102, which includes any of a variety of suitable materials, such as quartz or silicon. The substrate 102 and the stamp layer 104 are collectively referred to herein as the “working stamp workpiece 108” or “stamp workpiece 108”.

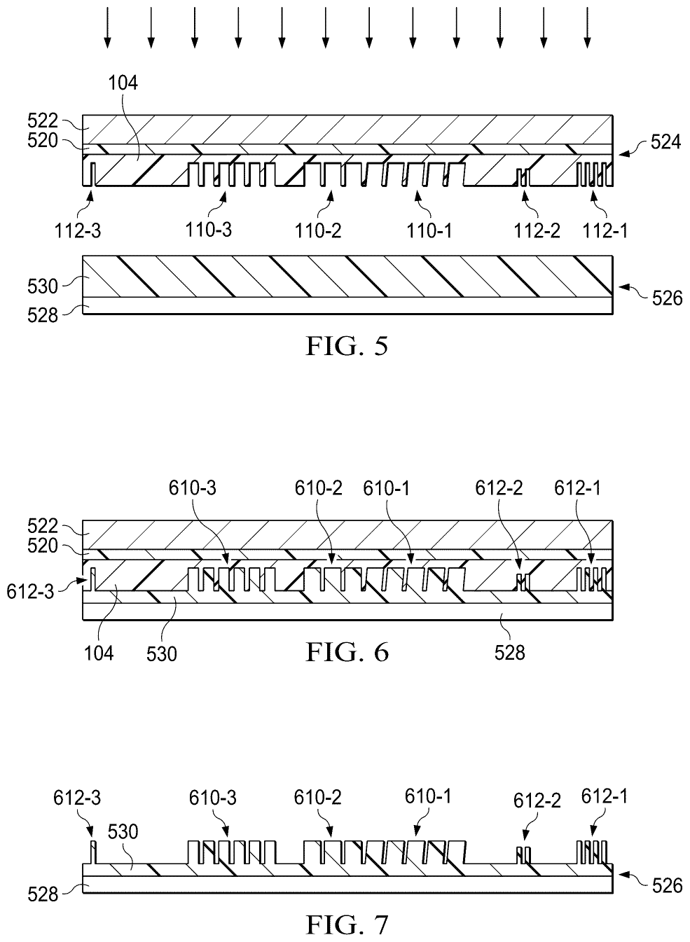

In the initial arrangement shown in FIG. 1, the master stamp 106 is positioned above and separated from the stamp layer 104, relative to the orientation of the view shown. The master stamp 106 includes one or more waveguide feature patterns 110 corresponding to waveguide features, such as gratings, that will form the final waveguide(s) on a waveguide workpiece 526 (FIG. 5). For example, the master stamp 106 includes a first set of waveguide feature patterns 110-1, a second set of waveguide feature patterns 110-2, and a third set of waveguide feature patterns 110-3 corresponding to functional elements or features (e.g., gratings) of a final waveguide. The master stamp 106 also includes one or more process control feature patterns 112 corresponding to process control features to be formed in non-functional zones of the waveguide workpiece 526. For example, the master stamp 106 includes a first set of process control feature patterns 112-1, a second set of process control feature patterns 112-2, and a third set of process control feature patterns 112-3 corresponding to the process control features described herein.

In at least some embodiments, the master stamp 106 is composed of a substrate, such as a silicon wafer or quartz plate, although other materials are also applicable. The master stamp 106, in at least some embodiments, is formed by is formed cleaning the substrate to remove any contaminants that could affect the patterning process. A uniform layer of photoresist or electron-beam resist is then applied to the substrate using a spin-coating process. The designed patterns, including waveguide feature patterns 110 corresponding to desired waveguide features and additional features 112 corresponding to directed process control features, are then transferred onto the resist layer using high-resolution lithography techniques, such as electron beam lithography (EBL) or photolithography. Once the patterns are written, the resist is developed to reveal the patterned areas, creating openings in the resist layer. Next, the exposed areas of the substrate are etched using, for example, reactive ion etching (RIE) or wet etching. After etching, any remaining resist is removed using a solvent wash or plasma ashing, cleaning the substrate and revealing the etched patterns. Once the waveguide feature patterns 110 and process control feature patterns 112 have been etched into the master stamp 106, the master stamp 106 undergoes final inspection using microscopy techniques to ensure precision and identify any defects. In at least some embodiments, an anti-sticking layer, such as a fluorosilane coating, is applied to the master stamp 106 to facilitate the release of the working stamp during the imprinting process.

Although a single master stamp 106 is shown in FIG. 1, in at least some embodiments, multiple master stamps 106 are implemented. For example, FIG. 2 shows multiple master stamps 106 (illustrated as master stamp 106-1 to master stamp 106-5) each configured with one or more feature patterns. In the illustrated example, a first master stamp 106-1 includes a first set process control feature patterns 112-1, a second master stamp 106-2 includes a second set process control feature patterns 112-2, a third master stamp 106-3 includes a first set of waveguide feature patterns 110-1 and a second set of waveguide feature patterns 110-2, a fourth master stamp 106-4 includes a third set of waveguide feature patterns 110-3, and a fifth master stamp 106-5 includes a third set process control feature patterns 112-3.

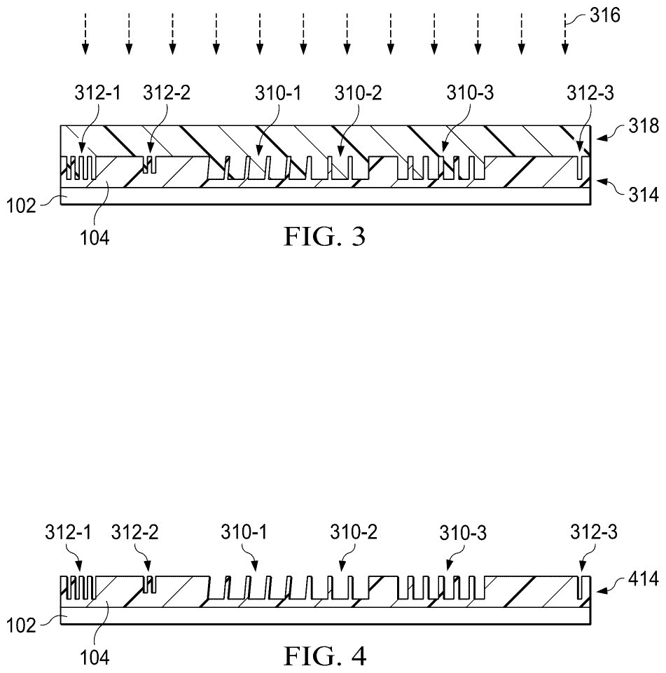

In at least some embodiments, a working stamp lithography process is initiated by aligning the master stamp 106 with the stamp workpiece 108, such as by using alignment marks or other similar alignment tools, and then pressing the master stamp 106 into the stamp layer 104, as shown in FIG. 3. This process imprints corresponding waveguide feature patterns 310 (illustrated as feature patterns 310-1 to feature patterns 310-3) and corresponding process control feature patterns 312 (illustrated as feature patterns 312-1 to feature patterns 312-3) from the first master stamp 106 into the stamp layer 104. In the illustrated example, the waveguide feature patterns 110 and the process control features 112 of the master stamp 106 are complimentary or negative to the resulting waveguide feature patterns 310 and process control feature patterns 312 formed in the stamp layer 104. In at least some embodiments, the waveguide feature patterns 110 are located in one or more functional waveguide zones of the stamp layer 104 for forming surface grating features in the waveguide workpiece 526, and the process control feature patterns 312 are formed in one or more regions outside of the one or more functional waveguide zones of the stamp layer 104.

After the master stamp 106 has been pressed into the stamp layer 104, a local ultraviolet (UV) cure process is performed on the resulting workpiece 314 by applying UV light 316 to the region underlying the master stamp 106 while the master stamp 106 remains embedded in the stamp layer 104. In at least some implementations, this is achieved by forming the master stamp 106 using a polymer or other stamp material that is transparent or semi-transparent to UV light, thereby allowing the UV light 316 applied to a top side 318 of the master stamp 106 to transmit through the master stamp 106 to the underlying material of the stamp layer 104. If any regions of the stamp layer 104 are exposed, a mask overlying the workpiece 314 may be used to prevent UV light from prematurely curing these exposed regions.

After the UV curing process has been completed, the master stamp 106 is detached from the stamp layer 104, resulting in a stamp workpiece 414 that has waveguide feature patterns 310 and process control feature patterns 312, as shown in FIG. 4. If multiple master stamps 106 are implemented, the imprinting, curing, and detachment processes described above are performed for each of the multiple master stamps 106 in a step-wise fashion. The waveguide feature patterns 310 of the stamp layer 104, in at least some embodiments, includes patterns of binary gratings, patterns of slanted gratings, a combination thereof, or the like. The waveguide feature patterns 310 are situated at locations on the stamp layer 104 such that, when the stamp layer 104 is applied to a waveguide workpiece 526, the waveguide feature patterns 310 are transferred to the corresponding locations on the waveguide workpiece 526 where functional elements or features (e.g., gratings) of the final waveguide are to be formed.

The process control feature patterns 312 of the stamp layer 104 are situated at locations on the stamp layer 104 such that, when the stamp layer 104 is applied to a waveguide workpiece 526, the process control feature patterns 312 are transferred to the corresponding locations in non-functional zones or regions of the waveguide workpiece 526. Stated differently, the process control feature patterns 312 of the stamp layer 104 are situated at locations on the stamp layer 104 such that the process control feature patterns 312 are transferred to areas of the waveguide workpiece 526 outside of the areas where functional elements or features (e.g., gratings) of the final waveguide are to be formed. As described in greater detail below, the process control feature patterns 312 are configured with geometries (e.g., shapes and dimensions) that result in patterns of process control features being formed on the waveguide workpiece 526 that facilitate various aspects of the detachment process of a working stamp from the waveguide workpiece 526 during nanoimprint lithography.

After the master stamp 106 has been detached from the stamp layer 104, the stamp layer 104 is attached to a stamp tape 520, which is held by a stamp frame 522, as shown in FIG. 5. The stamp layer 104 and the stamp tape 520 are collectively referred to herein as the “working stamp 524”. The working stamp 524 and the stamp frame 522 are arranged above a waveguide workpiece 526, relative to the orientation of the view shown. The stamp tape 520, in at least some embodiments, is composed of a flexible plastic or other material. This flexibility of the stamp tape 520 allows the stamp tape to conform to the surface of the waveguide workpiece during the imprinting process. During the imprinting process, the stamp tape 520 helps transmit the force applied by a replication tool evenly across the surface of the waveguide workpiece. This ensures that the waveguide feature patterns 310 and the process control feature patterns 312 of the working stamp 524 are accurately and consistently transferred. The waveguide workpiece 526 includes a substrate 528 and waveguide material layer 530. The substrate 528 includes, for example, a transparent material, such as glass or polymer. The waveguide material layer 530 includes, for example, a transparent polymer or glass that can be patterned to form waveguide structures and the process control features described herein.

In at least some embodiments, waveguide lithography process is initiated by aligning the working stamp 524 with the waveguide workpiece 526, such as by using alignment marks or other similar alignment tools, and then pressing the working stamp 524 into the waveguide material layer 530, as shown in FIG. 6. As described above, the working stamp 524 has negative (inverse) patterns of the waveguide features and process control feature patterns to be formed on the waveguide workpiece 526. As such, this process imprints corresponding waveguide feature patterns 610 (illustrated as feature patterns 610-1 to feature patterns 610-3) and corresponding process control feature patterns 612 (illustrated as feature patterns 612-1 to feature patterns 612-3) into the waveguide material layer 530. After the waveguide feature patterns 610 and the process control feature patterns 612 have been imprinted into the waveguide workpiece 526, the working stamp 524 is detached from the waveguide workpiece 526, as shown in FIG. 7.

The process control feature patterns 610 improve the initiation of the working stamp detachment by evenly distributing the detachment forces across the waveguide workpiece 526, which reduces the likelihood of localized sticking or uneven detachment at the initial point of separation. Additionally, the process control feature patterns 610 enhance the continuity of the detachment process by evening out the distribution density in the middle regions of the waveguide workpiece 526, ensuring a stable and controlled separation of the working stamp 524 throughout the entire process. Finally, the process control feature patterns 610 help to reduce “popping”, which refers to the sudden release of the working stamp 524 as it detaches from the final areas of the waveguide workpiece 526. This mitigation prevents abrupt releases that could damage the patterned waveguide features, thereby protecting the integrity of the functional patterns on the waveguide.

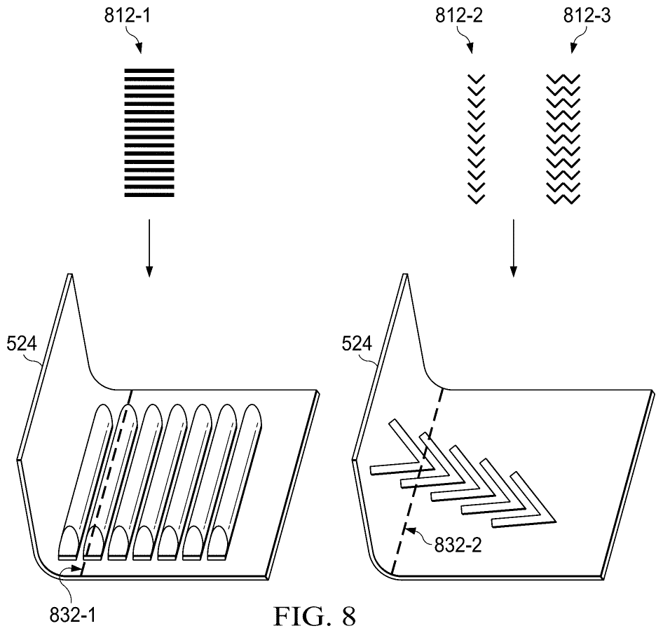

In at least some embodiments, the process control feature patterns 610 take the form of a series or set of bar-shaped features 812-1, as a series or set of “V”-shaped features 812-2, as a series or set of “W”-shaped features 812-3, a combination thereof, and the like, as shown in FIG. 8. The “V”-shaped features, in at least some embodiments, are characterized as geometric shapes formed by two straight lines or segments that meet at a common point, creating an angle that is typically less than 180 degrees. The lines are generally symmetric about a vertical axis, forming an open angle pointing downward. The shape may vary in thickness, length, and angle of convergence, but it consistently retains the characteristic of two diverging lines meeting at an apex. Similarly, the “W”-shaped features can be described as geometric shapes composed of four straight lines or segments. These lines form a sequence of two adjacent “V” shapes, creating a zigzag pattern. The structure includes three vertices where the lines change direction, with the middle vertex pointing downward and the outer vertices pointing upward. The lines are typically symmetric about a vertical axis through the middle vertex. As with the letter “V”, the shape may vary in thickness, length, and angle of the lines, but it maintains the overall zigzag configuration. FIG. 8 further shows the various points of contact 832 (illustrated as point of contact 832-1 and point of contact 832-2) of the working stamp 524 with the bar-shaped features 812-1, “V”-shaped features 812-2, and the “W”-shaped features 812-3, where the “V” or “W”-shape features 812 provide more than two points of contact for the working stamp 524.

The function of the sequence of process control feature patterns 610 may be understood using a zipline analogy in which the sequence of process control feature patterns 610 serves to aid in maintaining consistent contact between the working stamp 524 and the waveguide workpiece 526 during the detach process through improved workpiece surface pattern distribution and improved pattern density uniformity. As noted above, the process control feature patterns 610 generally are located in non-functional zones of the waveguide workpiece 526, as well as in regions in which they will not impact bar coding, singulation, or inline metrology processes. Each element of the process control feature patterns, in at least some embodiments, has length dimensions in, for example, the tens or hundreds of microns, width dimensions from, for example, 1 to 10 microns, and depth dimensions equivalent to the functional grating feature depths. The lengths of the “ziplines” of process control feature patterns 610, in at least some embodiments, is varied and broken into individual separate ziplines. The particular pattern shape selected may be based on the desired detachment control for the corresponding region. For example, a bar-shaped process control feature pattern 810-1 may provide more surface contact along a detach line parallel to the bar-shape, a double-V shaped process control feature patterns 810-3 may provide a moderate amount of surface contact along a detach line orthogonal to the zipline, while a V shaped process control feature pattern 810-2 may provide a lower amount of surface contact along the detach line.

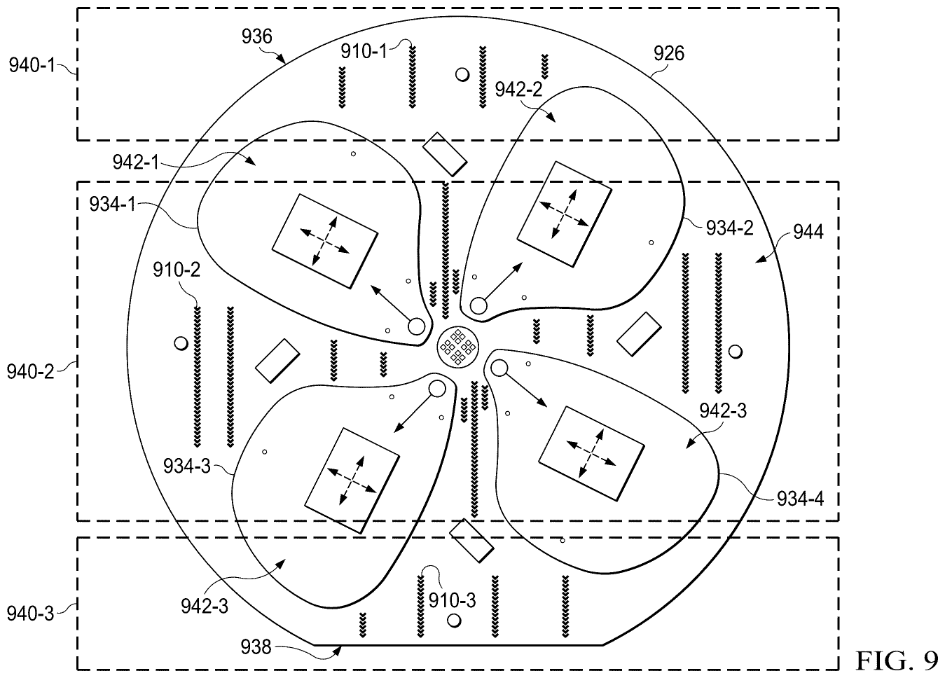

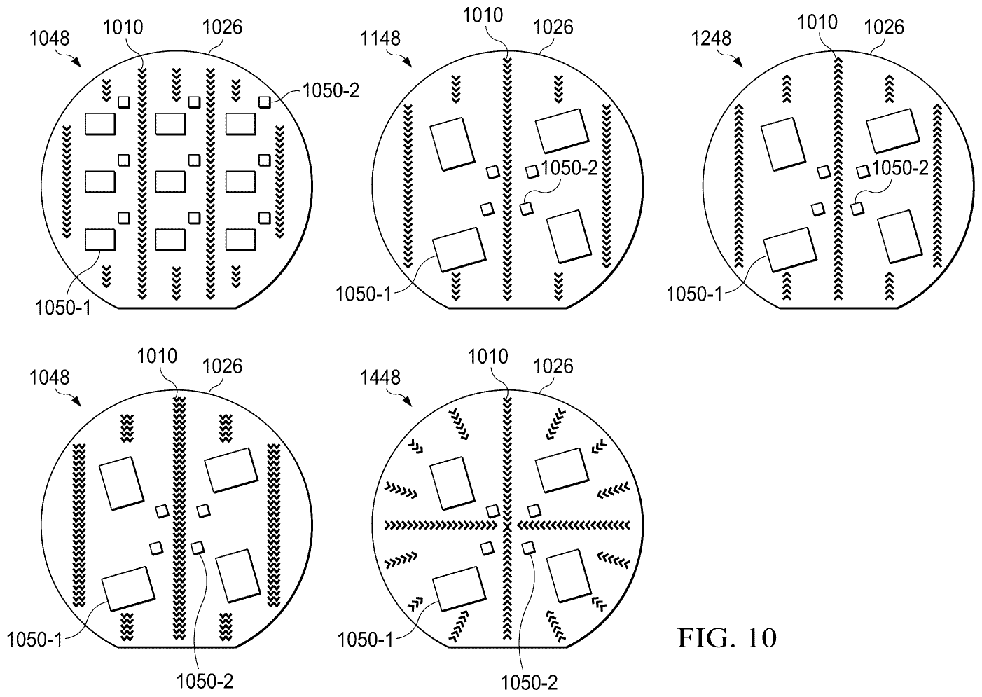

To illustrate the use and distribution of process control feature patterns 610 to facilitate working stamp detachment, FIG. 9 illustrates a top view of an example waveguide workpiece 926 in which four eyeglass lens-style waveguides 934 (illustrated as waveguide 934-1 to waveguide 934-4) are being fabricated in a pinwheel arrangement within the waveguide workpiece 926. In this example, the working stamp detachment initiates at the top 936 of the waveguide workpiece 926 (relative to the view orientation of FIG. 9) and proceeds straight down to the bottom 938 of the waveguide workpiece 926 (again, relative to the view orientation of FIG. 9). As highlighted in the top dotted-line box 940-1 of FIG. 9, a number of process control feature ziplines 910-1 are formed in portions of the top region 936 outside of the functional waveguide zones 942 (illustrated as waveguide zone 942-1 to waveguide zone 942-4) so as to optimize or otherwise improve working stamp detachment initiation through distribution of detachment forces as a result of the process control feature ziplines 910-1. As highlighted in the middle dotted-line box 940-2 of FIG. 9, a number of process control feature ziplines 910-2 are distributed in the working stamp in portions of a middle region 944 that are outside the functional waveguide zones 942 so as to even-out or otherwise improve the pattern distribution density in this middle region 946, and thus improve the detaching continuity of the working stamp 524 during the detachment process. As highlighted by the bottom dotted-line box 940-3 of FIG. 9, a number of process control feature ziplines 910-3 are distributed in portions of the bottom region 938 that are outside the functional waveguide zones 942 so as to mitigate the “popping” of the working stamp 524 off of the waveguide workpiece 526 that often may occur as the detachment of the working stamp reaches the end side of the waveguide workpiece during the detachment process.

Other layouts of the process control feature ziplines 910 than those illustrated in FIG. 9 are also applicable, such as those shown in FIG. 10. For example, one layout includes a step-repeat configuration 1048 of waveguide elements 1050 (illustrated as waveguide elements 1050-1 and waveguide elements 1050-2) on a waveguide workpiece 1026 with edge-to-edge distribution of the process control feature ziplines 1010. Another configuration presents a pinwheel layout 1148 of waveguide elements 1050 on a waveguide workpiece 1026 with edge-to-edge distribution of “V”-shaped process control feature ziplines 1010. A further configuration includes a pinwheel layout 1248 of waveguide elements 1050 on a waveguide workpiece 1026 with edge-to-edge distribution of reverse “V”-shaped process control feature ziplines 1010 is also shown. An additional configuration includes a pinwheel layout 1348 of waveguide elements 1050 on a waveguide workpiece 1026 with edge-to-edge distribution of “W”-shaped process control feature ziplines 1010. Another example includes a pinwheel layout 1448 of waveguide elements 1050 on a waveguide workpiece 1026 with a circular distribution of the process control feature ziplines 1010 for detaching a working stamp 524 in an edge-to-center direction.

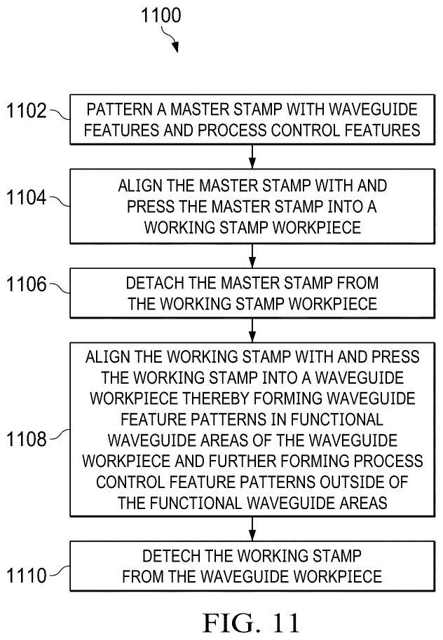

FIG. 11 is a diagram illustrating an example method 1100 of fabricating waveguide features in a waveguide workpiece and fabricating process control features in non-functional zones of the waveguide workpiece using nano-imprint lithography processes in accordance in accordance with at least some embodiments. It should be understood that the processes described below with respect to the method 1100 have been described above in greater detail with reference to FIG. 1 to FIG. 10. The method 1100 is not limited to the sequence of operations shown in FIG. 11, as at least some of the operations can be performed in parallel or in a different sequence. Moreover, in at least some implementations, the method 1100 can include one or more different operations than those shown in FIG. 11.

At block, 1102, a master stamp 106 is patterned with waveguide features 110 and process control features 112. At block 1104, the master stamp 106 is aligned with and pressed into a stamp workpiece 108 to form inverse waveguide feature patterns 310 and inverse process control feature patterns 312. In at least some embodiments, the inverse waveguide feature patterns 310 are formed in areas of the stamp workpiece 108 corresponding to functional waveguide zones of a waveguide workpiece 526 and the inverse process control feature patterns 312 are formed in areas of the stamp workpiece 108 corresponding to areas of the waveguide workpiece 526 that are outside of the functional waveguide zones.

At block 1106, the master stamp 106 is detached from the stamp workpiece 108 thereby forming a working stamp 524. At block 1108, the working stamp 524 is aligned with and pressed into the waveguide workpiece 526 thereby forming waveguide feature patterns 610 in functional waveguide zones and also forming process control feature patterns 612 in areas that are outside of the functional waveguide zones. At block 1110, the working stamp 524 is detached from the waveguide workpiece 526 with the process control feature patterns 612 improving the initiation of the detachment by evenly distributing the detachment forces across the waveguide workpiece 526, enhancing the continuity of the detachment process by evening out the distribution density in the middle regions of the waveguide workpiece 526, and reducing “popping” by mitigating abrupt releases as the working stamp 524 detaches from the final areas of the waveguide workpiece 526, thereby protecting the integrity of the patterned waveguide features 610.

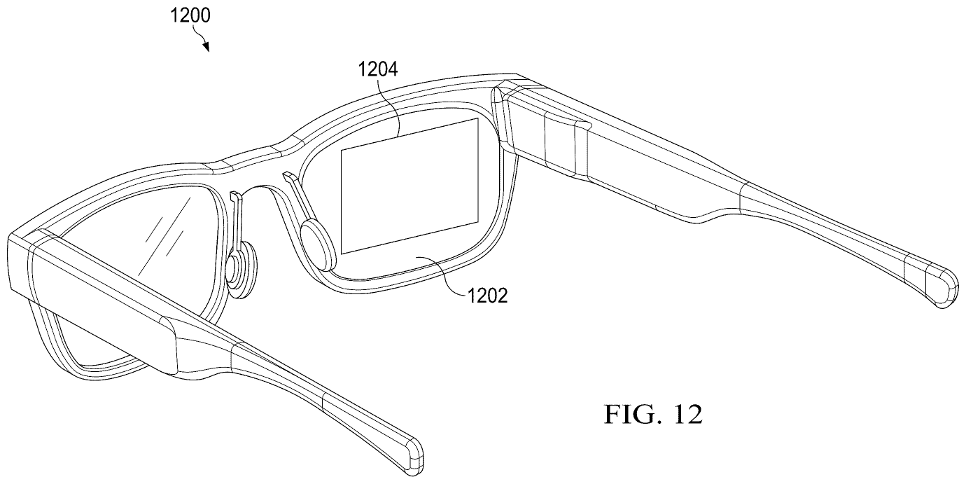

FIG. 12 illustrates a set of augmented reality (AR) glasses 1200 implementing a waveguide having been fabricated using a working stamp that employs process control feature patterns in accordance with FIG. 1 to FIG. 14 described above. As shown, the AR glasses 1200 include a set of lenses, including a lens 1202 incorporating a waveguide 1204. The waveguide 1204, in at least some embodiments, incorporates slanted, binary, or other surface gratings fabricated as described above, such as for an incoupler, an outcoupler, an exit-pupil-expander, or some other optical component of the waveguide.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A method comprising:
forming a working stamp having at least one waveguide feature pattern and at least one process control feature pattern;
pressing the working stamp into a waveguide workpiece thereby forming waveguide features in one or more functional waveguide zones of the waveguide workpiece and one or more sets of process control features in one or more regions outside of the one or more functional waveguide zones; and
detaching the working stamp from the waveguide workpiece.

2. The method of claim 1, wherein forming the working stamp comprises:
forming the at least one waveguide feature pattern in one or more functional waveguide zones of the working stamp corresponding to the one or more functional waveguide zones of the waveguide workpiece; and
forming the at least one process control feature pattern in at least one region of the working stamp outside of the one or more functional waveguide zones of the working stamp.

3. The method of claim 1, wherein forming the working stamp comprises:
distributing the at least one process control feature pattern in one or more regions of the working stamp outside of the one or more functional waveguide zones so as to improve local pattern density or uniformity of local contact between the working stamp and the waveguide workpiece.

4. The method of claim 1, wherein pressing the working stamp into the waveguide workpiece comprises:
forming a first set of process control features in a first region of the waveguide workpiece outside of the one or more functional waveguide zones; and
forming a second set of process control features in a second region of the waveguide workpiece outside of the one or more functional waveguide zones.

5. The method of claim 1, wherein pressing the working stamp into the waveguide workpiece comprises:
forming the one or more sets of process control features from a first edge of the waveguide workpiece to a second edge of the waveguide workpiece.

6. The method of claim 1, wherein forming the waveguide features comprises forming surface gratings.

7. The method of claim 1, wherein forming the working stamp comprises configuring the at least one process control feature pattern to have one or more of bar-shaped features, V-shaped features, reverse V-shaped features, or W-shaped features.

8. A stamp for waveguide nanoimprint lithography, comprising:
one or more functional waveguide zones;
at least one waveguide feature pattern formed within the one or more functional waveguide zones for forming waveguide features in at least one waveguide; and
at least one process control feature pattern formed in one or more regions outside of the one or more functional waveguide zones.

9. The stamp of claim 8, wherein the at least one process control feature pattern is distributed in the one or more regions so as to improve local pattern density or uniformity of local contact between the stamp and a waveguide workpiece.

10. The stamp of claim 8, wherein the least one waveguide feature pattern is configured to form surface gratings in a waveguide workpiece.

11. The stamp of claim 8, wherein the at least one process control feature pattern includes one or more of bar-shaped features, V-shaped features, reverse V-shaped features, or W-shaped features.
